(19) United States
(12) Patent Application Publication
(10) Pub. No.: US 2019/0062905 A1
(43) Pub. Date: Feb. 28, 2019

(54) SUBSTRATE PROCESSING DEVICE AND SHIELDING PLATE

(71) Applicant: TOSHIBA MEMORY CORPORATION, Tokyo (JP)

(72) Inventor: Nobuyoshi SATO, Kimitsu Chiba (JP)

(73) Assignee: TOSHIBA MEMORY CORPORATION, Tokyo (JP)

(21) Appl. No.: 15/902,673

(22) Filed: Feb. 22, 2018

(30) Foreign Application Priority Data
Aug. 23, 2017 (JP) 2017-160513

(51) Int. Cl. C23C 16/04; B08B 3/10; H01L 21/687; G03F 7/00

(52) U.S. Cl. CPC C23C 16/042; G03F 7/0002; H01L 21/68785; B08B 3/10

(57) ABSTRACT

A substrate processing device is described. A holding portion is disposed in a first chamber and holds a workpiece having a first region. A plate includes a film formed on a second region corresponding to the first region. The film is formed of a material different from a material forming the first region of the workpiece. The plate is arranged to shield the first region. Holes are formed along an outer periphery of the film and pass through the plate in a thickness direction.

### CROSS-REFERENCE TO RELATED APPLICATION

This application claims the benefit of and priority to Japanese Patent Application No. 2017-160513, filed Aug. 23, 2017, the entire contents of which are incorporated herein by reference.

### FIELD

An embodiment described herein relates generally to a substrate processing device and a shielding plate.

### BACKGROUND

There is known a technique of forming a liquid repellent layer on a workpiece, such as a template used for imprinting, using a shielding plate.

### DESCRIPTION OF THE DRAWINGS

FIG. 1 is a schematic sectional view illustrating an example of a configuration of a substrate processing device according to some embodiments;

FIG. 2 is a sectional view illustrating an example of a schematic configuration of a template;

FIGS. 3A and 3B are views schematically illustrating an example of a configuration of a shielding plate according to some embodiments;

FIGS. 4A and 4B are views schematically illustrating an example of a configuration of the shielding plate according to some embodiments;

FIGS. 5A to 5C are sectional views schematically illustrating an example of the order of a method of manufacturing the shielding plate according to some embodiments;

FIG. 6 is a sectional view schematically illustrating a state where a liquid repellent film of the template according to some embodiments is formed;

FIGS. 7A to 7C are schematic sectional views illustrating an example of the order of an imprinting method;

FIG. 8 is a block diagram illustrating an example of a schematic configuration of the substrate processing device according to some embodiments; and

FIGS. 9A to 9E are views schematically illustrating a substrate processing method according to a comparative example.

### DETAILED DESCRIPTION

Exemplary embodiments provide a substrate processing device capable of forming a liquid repellent layer on a desired region of a template, and a shielding plate.

According to some embodiments, a substrate processing device including a holding portion and a shielding plate is provided. The holding portion is disposed in a first chamber, and holds a workpiece having a first region. The shielding plate includes a film formed on a second region corresponding to the first region, formed of a material having a lower Mohs hardness than a material forming the first region of the workpiece, and capable of shielding the first region, and gas supply holes formed along the outer periphery of the film and passing through the shielding plate in a thickness direction.

Hereinafter, a substrate processing device, a shielding plate and a method of processing a template according to some embodiments will be described in detail with reference to the accompanying drawings. The present disclosure is not limited by the exemplary embodiments.

The substrate processing device may be a device for forming a liquid repellent film on a side surface of a pedestal portion of a template and a resist-facing surface (first surface) of the template excluding the pedestal portion. When the template is imprinted on resist on a wafer substrate, the liquid repellent film prevents the resist from infiltrating into the pedestal portion side surface from the pedestal portion of the template. The substrate processing device according to some embodiments maybe used for other workpieces other than the template.

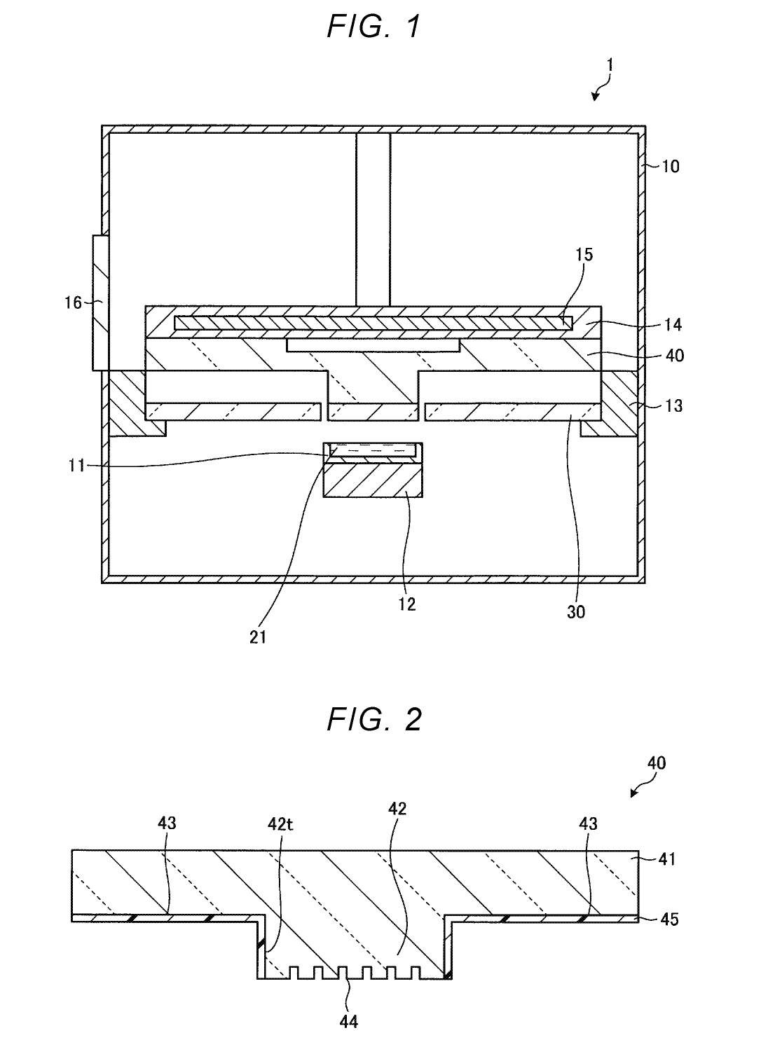

FIG. 1 is a sectional view schematically illustrating an example of a configuration of a substrate processing device according to the embodiment. A substrate processing device 1 includes a liquid repellent material holding portion 11 and a liquid repellent material heater 12 in a chamber 10, the liquid repellent material heater 12 serving as a liquid repellent material heating unit. The liquid repellent material holding portion 11 holds a liquid repellent material 21 which is used as a raw material of a liquid repellent film to be formed on a workpiece. The liquid repellent material 21 may include a fluorocarbon-based solvent, for example. The liquid repellent material heater 12 heats the liquid repellent material 21 in order to evaporate the liquid repellent material 21 which is held in the liquid repellent material holding portion 11.

The substrate processing device 1 further includes a shielding plate 30 provided in a space of the chamber 10 above the liquid repellent material holding portion 11. The detailed structure of the shielding plate 30 will be described later. The shielding plate 30 is held by a shielding plate holding portion 13 provided on the inner wall of the chamber 10, for example. The shielding plate holding portion 13 holds the edge portion of the shielding plate 30 such that the shielding plate 30 is horizontally held.

The substrate processing device 1 further includes a holding portion 14 and a heater 15 serving as a heating unit which are provided in a space of the chamber 10 above the shielding plate 30. The holding portion 14 holds a workpiece 40 on which a liquid repellent film is to be formed. In some embodiments, the workpiece may be a template, for example. The holding portion 14 holds the template such that a pattern formation surface of the template faces downward (toward the shielding plate 30). Hereinafter, the workpiece 40 will be described as the template 40. The holding portion 14 holds the template 40 in a vacuum chucking mechanism or electrostatic chucking mechanism, and can be moved in the vertical direction. The heater 15 serves to maintain the template 40 at a predetermined temperature while a liquid repellent film is formed. In the example of FIG. 1, the heater 15 is encompassed in the holding portion 14.

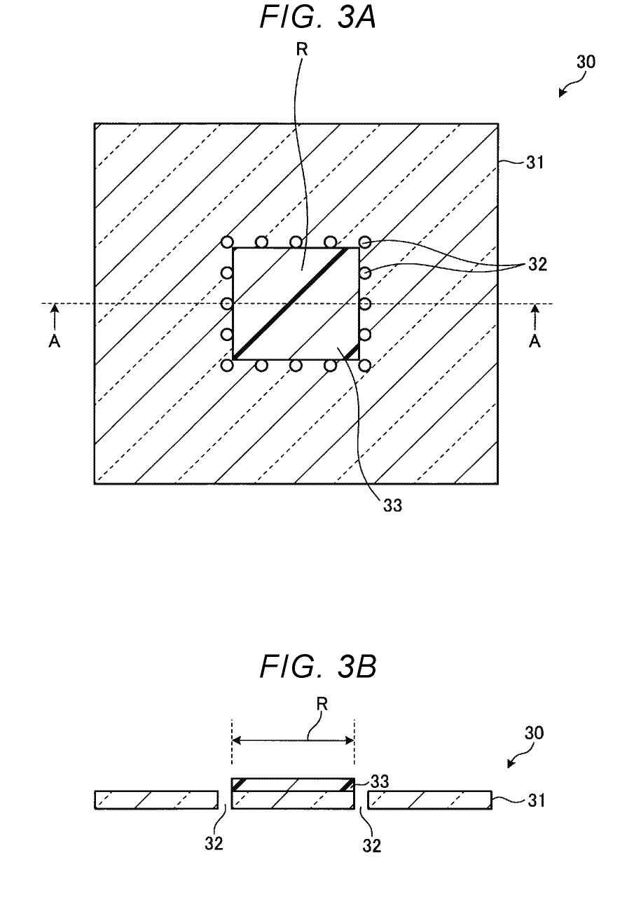

FIG. 2 is a sectional view illustrating an example of a schematic configuration of the template according to the embodiment. The template 40 may be formed by processing a rectangular template substrate 41. Around the center of a first surface 43 of the template substrate 41 (a surface facing the shielding plate), a pedestal (mesa) portion 42 may be provided, the pedestal portion 42 having an uneven pattern which is brought in contact with resist on a substrate (not illustrated) during an imprinting process. The pedestal portion 42 may have a mesa structure protruding from the first surface 43. Since the surface of the pedestal portion 42, facing the shielding plate, has an uneven pattern provided thereon, the surface becomes the pattern formation surface 44. Through the template process according to some embodiments, a liquid repellent film 45 is provided on the pedestal portion side surface 42t and the first surface 43. The template substrate 41 is formed of quartz glass, for example.

Referring back to FIG. 1, the chamber 10 has an opening provided at a side surface thereof, and a gate valve 16 is provided in the opening such that the opening is covered by the gate valve 16. The template 40 and the shielding plate 30 are loaded into the chamber 10 or unloaded from the chamber 10 through the opening.

The chamber 10 may include an exhaust unit to adjust the internal pressure of the chamber 10 to a predetermined value. The exhaust unit may include a vacuum pump, for example.

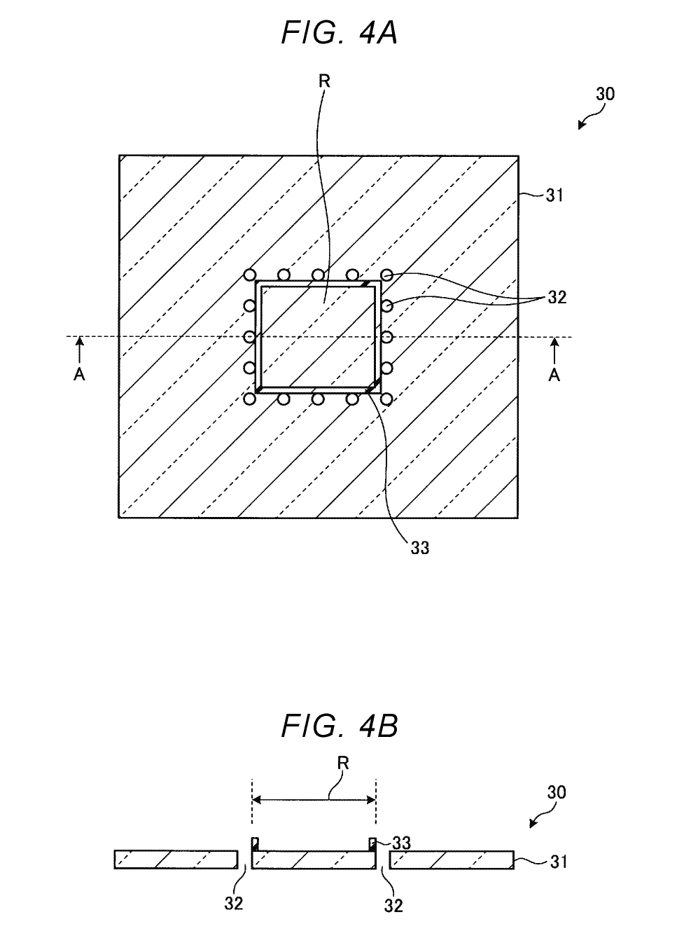

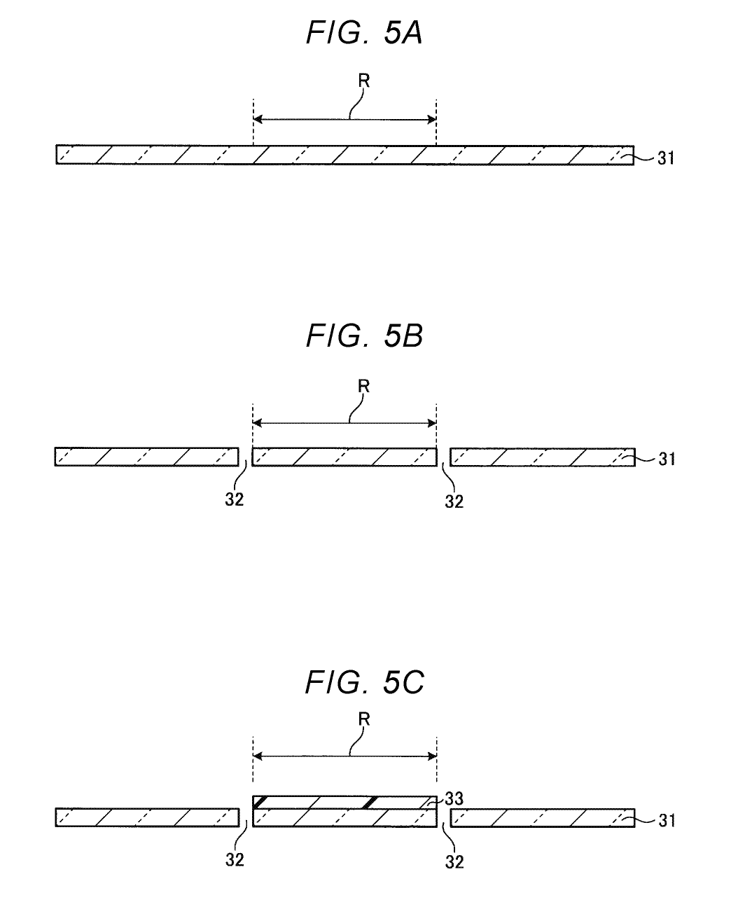

Next, the shielding plate 30 is described. FIGS. 3A to 4B are views schematically illustrating configuration examples of the shielding plate according to some embodiments. FIGS. 3A and 4A are plan views illustrating the surface facing the template, and FIGS. 3B and 4B are sectional views taken along the line A-A of FIGS. 3A and 4A. The shielding plate 30 may be formed by a rectangular plate 31, for example. A region of the plate 31, which comes in contact with the pattern formation surface 44 (pedestal portion 42) of the template 40 when the liquid repellent film is formed, is set to a shielding region R. When the template 40 is brought in contact with the shielding plate 30, the shielding region R completely covers the pattern formation surface 44 of the template 40. The shielding region R may be preferably set to the same size as the pattern formation surface 44, such that the liquid repellent film is not formed on the pattern formation surface 44. However, the shielding region R may have a larger size than the pattern formation surface 44. That is, the shielding region R may have the same size as the surface of the pedestal portion 42, facing the shielding plate 30. The shielding plate 30 may be formed of quartz glass, for example.

The shielding plate 30 has gas supply holes 32 provided at predetermined intervals along the outer periphery of the shielding region R. The gas supply holes 32 are provided so as to pass through the plate 31 in the thickness direction of the plate 31. The shielding region R corresponds to the inside of a region formed by sequentially connecting the gas supply holes 32 using a line. The gas supply holes 32 are provided in order to supply the liquid repellent material 21 to the template 40 in the substrate processing device 1 of FIG. 1, where the liquid repellent material 21 may be evaporated from the liquid repellent material holding portion 11.

The shielding region R of the shielding plate 30 has a low hardness film 33 provided on at least the peripheral edge thereof. The low hardness film 33 may be formed of, for example, a material having a lower Mohs hardness than the material forming the template 40. When the liquid repellent film is formed, the pattern formation surface 44 of the template 40 is brought in contact with the shielding plate 30. In this case, the material having a lower Mohs hardness than the material forming the template 40 is selected in order to protect the pattern formation surface 44 from the contact. The template 40 may be formed of quartz glass, for example. Since quartz glass has a Mohs hardness of 5.5 to 6.5, a material having a lower Mohs hardness than quartz glass is selected as the low hardness film 33. The low hardness film 33 may have a thickness of 3 nm or more. Desirably, the low hardness film 33 may have a thickness of 5 to 100 nm.

The low hardness film 33 is formed of a material having lower surface energy than the material forming the template 40. Typically, organic contaminants such as a liquid repellent material or contaminants such as inorganic particles from around are adsorbed onto the shielding plate 30. If the low hardness film 33 is formed of a material having higher surface energy than the material forming the template 40, contaminants may be transferred onto the template 40 from the shielding plate 30 when the shielding plate 30 is brought close to the template 40 to be in contact therewith during the process of forming the liquid repellent film. However, when the shielding plate 30 is brought close to the template 40 to be in contact therewith after the low hardness film 33 is formed of a material having lower surface energy than the material forming the template 40, contaminants can be prevented from being transferred onto the template 40 from the shielding plate 30.

When the template 40 is formed of quartz glass, the low hardness film 33 may be formed of photocurable resin or thermosetting resin having a lower Mohs hardness than quartz glass. Moreover, the low hardness film 33 is desirably formed of a polymer material with an alkyl group or a silyl group. Examples of the polymer material may include PDMS (polydimethylsiloxane) which is a silicon-based material. The PDMS is a rubbery film. Furthermore, C₈F₁₃H₄Si (OCH₃)₃ may be exemplified as a fluorocarbon material.

As illustrated in FIGS. 3A and 3B, the low hardness film 33 may be provided on the entire shielding region R. Moreover, in order to reduce a contact area between the low hardness film 33 and the pattern formation surface 44 of the template 40 as much as possible, the low hardness film 33 may be provided along the peripheral edge of the shielding region R as illustrated in FIGS. 4A and 4B. The reduction of the contact area can decrease the possibility that impurities might be transferred to the uneven pattern from the low hardness film 33. Furthermore, the low hardness film 33 may be provided on the inner walls of the gas supply holes 32 or regions other than the shielding region R facing the template 40. As described above, the low hardness film 33 is provided on at least the peripheral edge of the shielding region R, so that it is possible to prevent mixing and adsorption of the liquid repellent material onto the pattern formation surface 44.

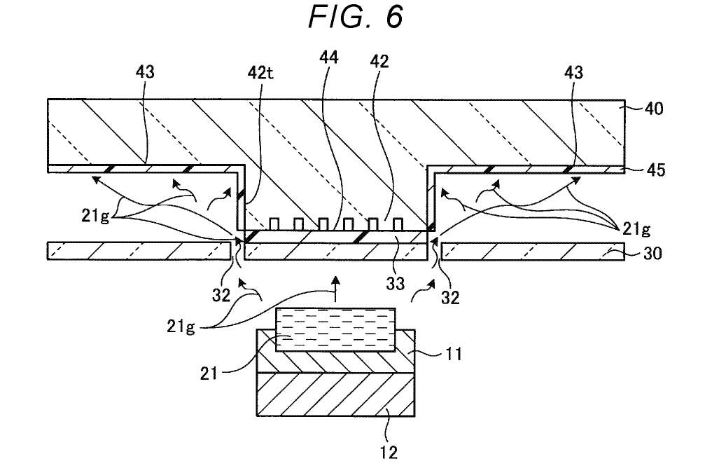

Hereinafter, a method of manufacturing the shielding plate 30 will be described. FIGS. 5A to 5C are sectional views schematically illustrating an example of the method of manufacturing the shielding plate according to some embodiments. First, as illustrated in FIG. 5A, a rectangular plate 31 is prepared. The plate 31 is formed of quartz glass, for example. Then, as illustrated in FIG. 5B, gas supply holes 32 are formed at predetermined intervals along the outer periphery of a region which becomes the shielding region R of the plate 31. The gas supply holes 32 may be formed by a machining center or laser processing device, for example.

Then, as illustrated in FIG. 5C, a low hardness film 33 is formed on at least a region of the plate 31, including the shielding region R, by an ALD (Atomic Layer Deposition) method or a CVD (Chemical Vapor Deposition) method. When the ALD method is applied, a low hardness film 33 with one atomic layer is formed. Furthermore, a low hardness film 33 having a plurality of atomic layers stacked therein may be formed, the plurality of atomic layers being formed through ALD cycles in which one atomic layer is formed and then the surface is oxidized to form another atomic layer on the atomic layer. When the CVD method is applied, a low hardness film 33 with continuity of a certain thickness is formed.

When the low hardness film 33 is formed only on the shielding region R, the other region of the plate 31 excluding the shielding region R is covered with a mask such as resist, and the low hardness film 33 is formed according to the above-described method. Furthermore, when the low hardness film 33 may be formed on the other region of the plate 31 in addition to the shielding region R, the low hardness film 33 is formed according to the above-described method, without masking the surface of the plate 31.

When the low hardness film 33 formed through the ALD method or CVD method is not cured, ultraviolet irradiation or heating is performed after the low hardness film 33 is formed. When the low hardness film 33 is formed of photocurable resin, the low hardness film 33 is cured by ultraviolet ray irradiated on the low hardness film 33. When the low hardness film 33 is formed of thermosetting resin, the low hardness film 33 is cured by heating the plate 31. In this way, the shielding plate 30 may be formed.

The above-described method of manufacturing the shielding plate 30 is merely exemplary, and the shielding plate 30 may be manufactured by other methods. For example, after the low hardness film 33 is formed on the plate 31, the gas supply holes 32 may be formed. Moreover, a solvent serving as a raw material of the low hardness film 33 may be dropped on the shielding region R of the plate 31, such that the surface of the plate 31 including the shielding region R is coated with the solvent according to a spin coating method. Then, the solvent may be cured by ultraviolet irradiation or heating, thereby forming the low hardness film 33. Furthermore, a solvent serving as the raw material of the low hardness film 33 may be formed on the peripheral edge of the shielding region R of the plate 31 by a printing method such as an inkjet method or a screen printing method, or a sheet of PDMS maybe attached on the peripheral edge of the shielding region R of the plate 31.

Next, a method of processing the template 40 using the substrate processing device 1 will be described with reference to FIG. 1. First, the gate valve 16 of the substrate processing device 1 is opened to place the shielding plate 30 on the shielding plate holding portion 13 in the chamber 10, with the low hardness film 33 set to the side facing the template. The shielding plate 30 is cleaned before a liquid repellent treatment is performed on the template. Furthermore, the template 40 having the uneven pattern formed thereon is held by the holding portion 14 in the chamber 10. The template 40 is held by the holding portion 14 such that the pattern formation surface 44 (pedestal portion 42) faces the shielding plate 30. Then, the gate valve 16 is closed.

Then, the template 40 and the shielding plate 30 are aligned with each other, and the holding portion 14 is lowered (toward the shielding plate 30) until the pattern formation surface 44 of the template 40 comes in contact with the low hardness film 33 of the shielding plate 30. The low hardness film 33 has a lower Mohs hardness than the template 40. Thus, even if the low hardness film 33 and the template 40 are brought in contact with each other, the pattern formation surface 44 of the template 40 is not damaged. Furthermore, the surface energy of the low hardness film 33 is smaller than that of the template 40. Thus, while the low hardness film 33 is brought close to the template 40 to be in contact therewith, organic contaminants or contaminants such as inorganic particles which are adsorbed onto the shielding plate 30 are not transferred onto the template 40.

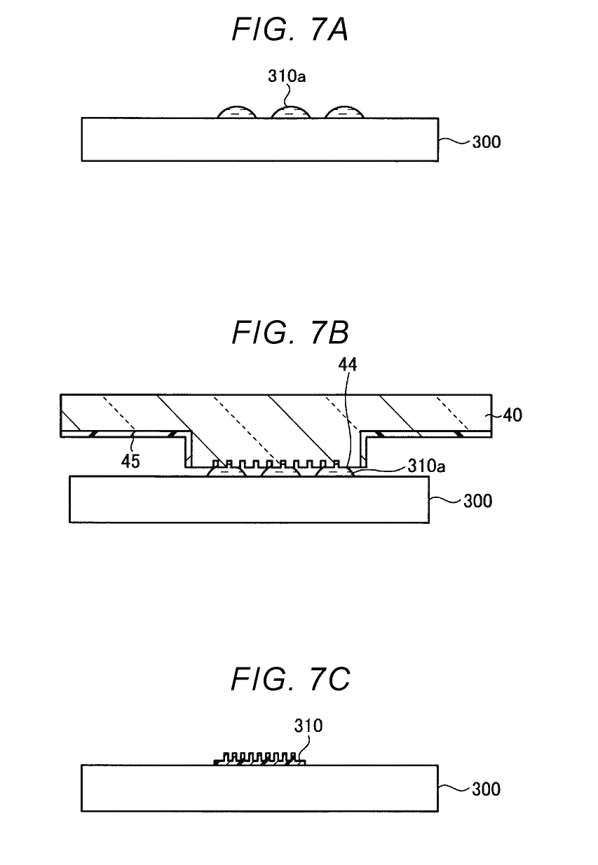

Then, the fluorocarbon-based liquid repellent material 21 held in the liquid repellent material holding portion 11 is heated and evaporated by the liquid repellent material heater 12. FIG. 6 is a sectional view schematically illustrating a state where the liquid repellent film of the template, according to the embodiment, is formed. As illustrated in FIG. 6, the evaporated liquid repellent material 21g adheres to the bottom surface of the template 40, that is, the first surface 43 and the pedestal portion side surface 42t of the template 40 through the gas supply holes 32 of the shielding plate 30. Moreover, when the shielding plate 30 having the structure illustrated in FIGS. 3A and 3B is used, since the pattern formation surface 44 is in contact with the low hardness film 33 of the shielding plate 30, the evaporated liquid repellent material 21g is not adsorbed onto the pattern formation surface 44. Furthermore, even when the shielding plate 30 having the structure illustrated in FIGS. 4A and 4B is used, since the low hardness film 33 of the shielding plate 30 is in contact with only the peripheral edge of the pattern region, the most part of the pattern region is not in contact with the shielding plate 30, and the evaporated liquid repellent material 21g is not adsorbed onto the pattern formation surface 44. At this time, the template 40 may be heated to a predetermined temperature by the heater 15. After a predetermined time is passed, the liquid repellent material heater 12 and the heater 15 are stopped to cool the template 40. In this way, the liquid repellent film 45 may be formed on the pedestal portion side surface 42t and the first surface 43 of the template 40.

Then, the gate valve 16 is opened to take the template 40 and the shielding plate 30 out of the chamber 10, and then closed. The taken-out template 40 may be used for an imprinting process.

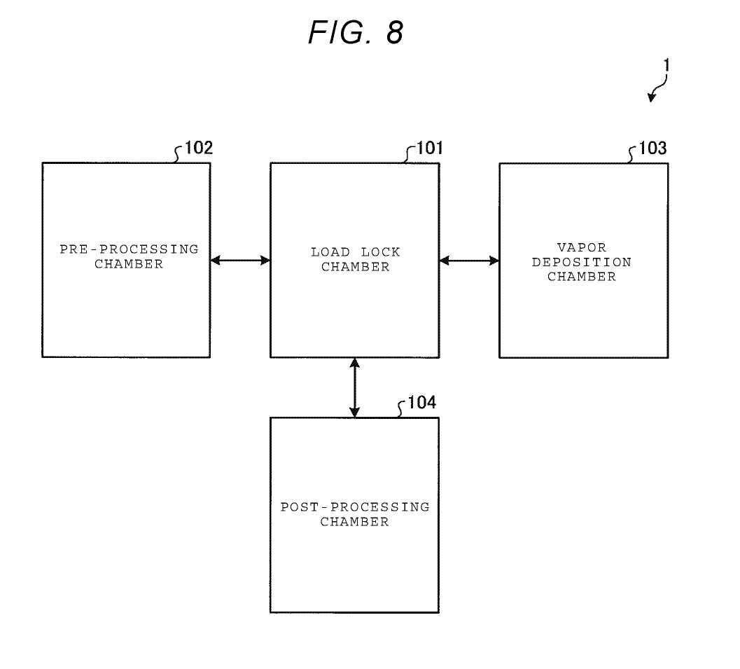

FIGS. 7A to 7C are sectional views schematically illustrating an example of the order of an imprinting method. In the imprinting method, resist 310a is applied onto a semiconductor substrate 300 as illustrated in FIG. 7A. Then, as illustrated in FIG. 7B, the pattern formation surface 44 of the template 40 having the liquid repellent film 45 formed thereon is stamped onto the resist 310a to cure the resist 310a. Then, as illustrated in FIG. 7C, the template 40 is separated from the resist such that the cured resist pattern 310 is transferred onto the semiconductor substrate 300. In this way, the method of processing the template 40 is ended. At this time, the resist or the fluorocarbon-based film may be adsorbed or adhere onto the template and the shielding plate 30 which were used for the imprinting process. Thus, when the liquid repellent film 45 is formed on the template, cleaning is performed as a pretreatment.

The low hardness film 33 provided on the shielding plate 30 may be repeatedly used until the low hardness film 33 deteriorates or cannot be used. Alternatively, the low hardness film 33 may be replaced at each imprinting process. When the low hardness film 33 is replaced, a solvent or oil may be permeated into the low hardness film 33 in order to swell the low hardness film 33, and the low hardness film 33 may be removed from the plate 31. Then, the plate 31 may be cleaned, and a new low hardness film 33 may be formed on the plate 31 according to the above-described order. Moreover, even when the low hardness film 33 deteriorates or cannot be used, the low hardness film 33 may be replaced according to the same order.

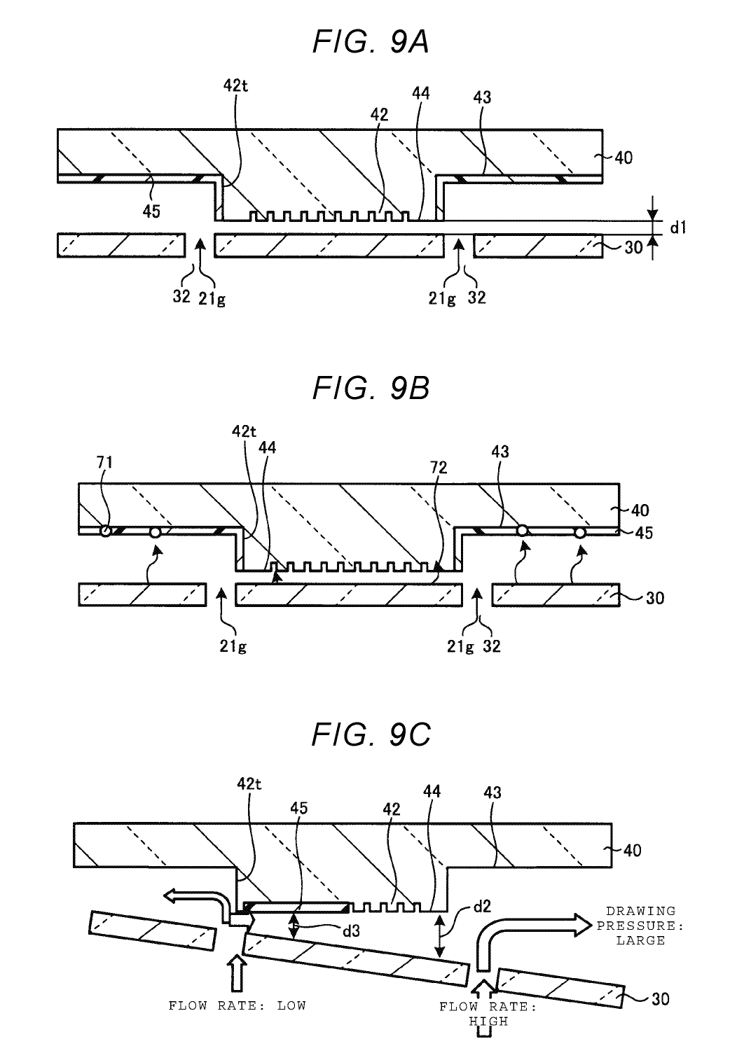

The substrate processing device 1 forms the liquid repellent film 45 on the template 40 using the shielding plate 30, but may have a function of performing various treatments on the shielding plate 30. FIG. 8 is a block diagram illustrating an example of the schematic configuration of the substrate processing device according to some embodiments. The substrate processing device 1 includes a load lock chamber 101, a pre-processing chamber 102, a vapor deposition chamber 103 and a post-processing chamber 104. The load lock chamber 101 maybe disposed adjacent to the pre-processing chamber 102, the vapor deposition chamber 103, and the post-processing chamber 104. The load lock chamber 101 serves as a relay chamber when the template 40 transferred from outside is transferred to the vapor deposition chamber 103 without being opened to the air. Furthermore, the load lock chamber 101 also serves as a relay chamber when the shielding plate 30 is transferred among the pre-processing chamber 102, the vapor deposition chamber 103, and the post-processing chamber 104 without being opened to the air.

The pre-processing chamber 102 maybe a processing chamber for removing unnecessary matters before vapor deposition or performing base modification. Specifically, the pre-processing chamber 102 may be used for cleaning the shielding plate 30 or forming the low hardness film 33 on the shielding plate 30. The pre-processing chamber 102 may include, for example, a cleaning device, ALD equipment, CVD equipment, a spin coating device or an inkjet device disposed therein.

The vapor deposition chamber 103 maybe a chamber for forming the liquid repellent film 45 on the template 40. The vapor deposition chamber 103 may be formed by the chamber 10 including the shielding plate 30 illustrated in FIG. 1 therein, for example.

The post-processing chamber 104 may be a processing chamber for removing unnecessary matter after vapor deposition or performing modification. Specifically, the post-processing chamber 104 may be used for removing the low hardness film 33 of the shielding plate 30. The post-processing chamber 104 may perform a process of swelling the low hardness film 33 by permeating a solvent or oil into the low hardness film 33, and removing the swollen low hardness film 33.

The process of the substrate processing device 1 is schematically described, according to some embodiments. For example, the template 40 and the shielding plate 30 are loaded into the load lock chamber 101 from outside. The shielding plate 30 is transferred to the pre-processing chamber 102 and cleaned in the pre-processing chamber 102. Then, the low hardness film 33 is formed on the shielding region R of the plate 31. Then, the shielding plate 30 is transferred to the vapor deposition chamber 103 from the pre-processing chamber 102 through the load lock chamber 101. Moreover, the template 40 is transferred to the vapor deposition chamber 103 from the load lock chamber 101. In the vapor deposition chamber 103, a liquid repellent treatment is performed to form the liquid repellent film 45. When the liquid repellent treatment is completed, the template 40 is transferred to the load lock chamber 101 from the vapor deposition chamber 103, and transferred to the outside, for example, as an imprinting device. Furthermore, the shielding plate 30 is transferred to the post-processing chamber 104 from the vapor deposition chamber 103 through the load lock chamber 101. In the post-processing chamber 104, the low hardness film 33 is removed. When the low hardness film 33 is removed, the shielding plate 30 is transferred to the pre-processing chamber 102 through the load lock chamber 101. The removing of the low hardness film 33 may be performed when the low hardness film 33 deteriorates or cannot be used any more.

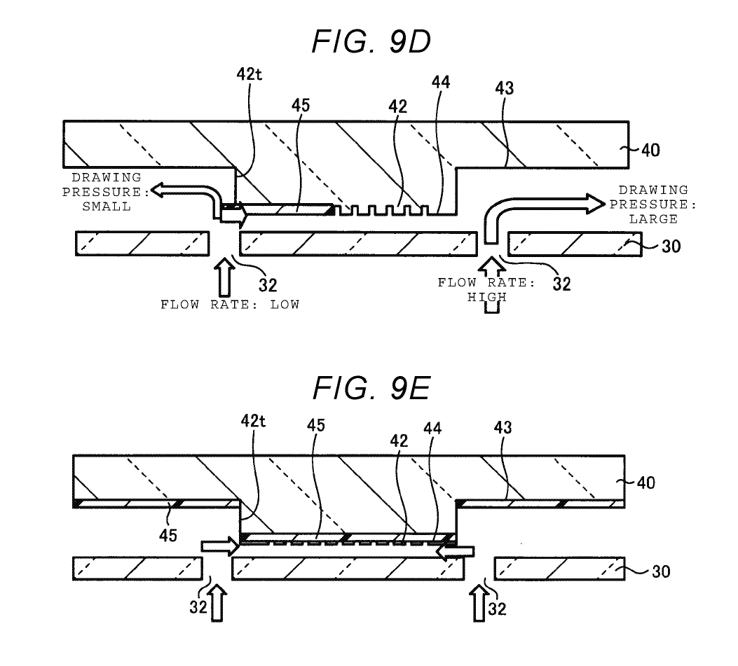

Hereinafter, the effect of the embodiment will be described in comparison to a comparative example. FIGS. 9A to 9E are views schematically illustrating a substrate processing method according to a comparative example. In the comparative example as illustrated in FIG. 9A, the template 40 and the shielding plate 30 are disposed with a gap d1, and the liquid repellent material 21g evaporated from the gas supply holes 32 adheres to the pedestal portion side surface 42t and the first surface 43 of the template 40. The gap d1 may be set to 5 μm, for example. In the comparative example, the low hardness film 33 is not formed on the shielding region R of the shielding plate 30. When the template 40 is brought in contact with the shielding plate 30, the pattern formation surface 44 of the template 40 may be damaged. Thus, in the comparative example, the gap d1 is provided between the pattern formation surface 44 and the shielding plate 30.

When the template 40 is brought close to the shielding plate 30 as illustrated in FIG. 9B with the gap d1 provided between the template 40 and the shielding plate 30, organic contaminants 71 or inorganic particles 72 adhered to the shielding plate 30 are adsorbed onto the pattern formation surface 44 by static electricity. The adsorbed organic contaminants 71 or the particles 72 may serve as a factor that causes a pattern defect, which is not preferable.

When the template 40 and the shielding plate 30 are disposed within a distance, the distance between the pattern formation surface 44 of the template 40 and the shielding plate 30 have to be precisely controlled to be d1 in all regions. When the distance is not precisely controlled as illustrated in FIG. 9C, the distance between the pattern formation surface 44 and the shielding plate 30 may vary as indicated by d2 and d3. The variation may cause differences between air flows from the gas supply holes 32, and the liquid repellent film 45 maybe formed on the pattern formation surface 44. In the case of FIG. 9C, the rate of air flow in a portion where the distance between the pattern formation surface 44 and the shielding plate 30 is large becomes higher than the rate of air flow in a portion where the distance between the pattern formation surface 44 and the shielding plate 30 is small. Thus, the air flow in the portion where the distance between the pattern formation surface 44 and the shielding plate 30 is small may be drawn toward the air flow in the portion where the distance between the pattern formation surface 44 and the shielding plate 30 is large. In this case, the liquid repellent film 45 may be formed on the pattern formation surface 44.

Moreover, even if the distance between the pattern formation surface 44 of the template 40 and the shielding plate 30 is precisely controlled so as to be equally maintained in all regions, flow rates of gases supplied from the respective gas supply holes 32 may be different from each other as illustrated in FIG. 9D. In this case, a large pressure difference may occur therebetween such that the evaporated liquid repellent material 21g is drawn toward a portion where the pressure is high. In this case, the liquid repellent film 45 may also be formed on the pattern formation surface 44. Furthermore, even if the distance between the pattern formation surface 44 of the template 40 and the shielding plate 30 is controlled with high precision, the evaporated liquid repellent material 21g may infiltrate into the gap therebetween as illustrated in FIG. 9E, when the film forming process is performed for a long time. In this case, the liquid repellent film 45 is formed on the pattern formation surface 44.

To the contrary, in some embodiments, when the liquid repellent film 45 is formed on the first surface 43 and the pedestal portion side surface 42t of the template 40, the shielding region R of the shielding plate 30 is brought in contact with the pattern formation surface 44 of the mesa pedestal portion 42 of the template 40. Furthermore, the low hardness film 33 having a lower Mohs hardness than the template 40 is disposed on the shielding region R. Therefore, with the shielding plate 30 brought in contact with the template 40, the liquid repellent material 21g evaporated from the gas supply holes 32 of the shielding plate 30 is adsorbed onto the first surface 43 and the pedestal portion side surface 42t of the template 40, thereby forming the liquid repellent film 45. At this time, since the pattern formation surface 44 of the template 40 is in contact with the shielding plate 30, the evaporated liquid repellent material 21g does not adhere to the pattern formation surface 44, and the liquid repellent film 45 is formed on only the desired region. Furthermore, since the low hardness film 33 provided on the shielding plate 30 has a lower Mohs hardness than the template 40, a damage on the template 40 can be prevented even if the low hardness film 33 and the template 40 are brought in contact with each other. Furthermore, since the surface energy of the low hardness film 33 is smaller than the surface energy of the template 40, organic contaminants 71 or inorganic particles 72 adhering to the shielding plate 30 are not transferred onto the template 40 even if the shielding plate and the template 40 are brought close to each other to be in contact. Moreover, since the shielding plate 30 and the template 40 are brought in contact with each other, organic contaminants 71 or inorganic particles 72 adhering to the shielding plate 30 can be prevented from being adsorbed onto the pattern formation surface 44.

Furthermore, since no gap is provided between the pattern formation surface 44 of the template 40 and the shielding plate 30, it is possible to prevent a turbulence of air flow caused by a variation of the gap indifferent regions. Moreover, since the shielding plate 30 is brought in contact with the pattern formation surface 44, gas does not infiltrate into the pattern formation surface 44 even if the flow rates of gases from the respective gas supply holes 32 of the shielding plate 30 differ from each other. Therefore, the liquid repellent film 45 is not formed on the pattern formation surface 44.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A substrate processing device comprising:
a holder, disposed in a first chamber, that holds a workpiece having a first region made of a first material; and
a plate including a film formed on a second region, the second region positioned corresponding to the first region, the film formed of a second material different from the first material, the plate arranged to shield the first region; and
holes formed along an outer periphery of the film and extending through the plate in a thickness direction.

2. The substrate processing device according to claim 1, further comprising:
a plate holder that holds the plate with the plate in contact with the first region of the workpiece;
a liquid repellent material holder disposed at a side opposite to the workpiece from the plate holder in the first chamber, and holding a liquid repellent material therein; and
a heater configured to heat the liquid repellent material.

3. The substrate processing device according to claim 2, wherein the liquid repellent material includes a fluorocarbon based solvent.

4. The substrate processing device according to claim 1, wherein the film is formed of a material having smaller surface energy than the first material forming the workpiece.

5. The substrate processing device according to claim 1, wherein the film is formed of a silicon-based material or a fluorocarbon-based material having anyone of an alkyl group or a silyl group.

6. The substrate processing device according to claim 1, further comprising a heater arranged to heat the workpiece in the first chamber.

7. The substrate processing device according to claim 1, further comprising:
a second chamber different from the first chamber; and
a film forming device disposed in the second chamber and configured to form the film on the plate.

8. The substrate processing device according to claim 7, wherein the film forming device comprises at least one of ALD (Atomic Layer Deposition) equipment, CVD (Chemical Vapor Deposition) equipment, a spin coating device, or an inkjet device.

9. The substrate processing device according to claim 1, wherein the film is disposed only on a peripheral edge of the second region.

10. The substrate processing device according to claim 1, wherein the first region is a protruding pedestal portion of the workpiece.

11. The substrate processing device according to claim 10, wherein the first region includes a pattern formation surface of the pedestal portion.

12. The substrate processing device according to claim 1, wherein the second region has a same size or larger than a size of the first region.

13. A plate for use with a template comprising:
holes formed along an outer periphery of a first region for contacting a pedestal portion of the template, the holes extending through the plate in its thickness direction; and
a film formed on the first region, the film being formed of a material different from a material forming the template.

14. A method of processing a workpiece comprising:
providing a workpiece having a first region made of a first material;
providing a plate having a second region with a film formed thereon, the film being made of a second material different from the first material;
contacting the first region of the workpiece to the film formed on the plate; and
arranging the plate to shield the first region,
wherein holes are formed along an outer periphery of the film, the holes extending through the plate in a thickness direction.

15. The method of processing a workpiece according to claim 14, further comprising:
heating a liquid repellent material such that a liquid repellant film forms on a third region of the workpiece, without forming on the first region of the workpiece.

16. The method of processing a workpiece according to claim 14, wherein the film is disposed only on a peripheral edge of the second region.

17. The method of processing a workpiece according to claim 14, wherein the first region corresponds to a protruding pedestal portion of the workpiece.

18. The method of processing a workpiece according to claim 17, wherein the first region includes a pattern formation surface of the pedestal portion.

19. The method of processing a workpiece according to claim 18, wherein the pedestal portion has a mesa structure protruding from the pattern formation surface.

20. The method of processing a workpiece according to claim 14, wherein the second region has a same size or larger than a size of the first region.
